(19) United States
(12) Patent Application Publication
(10) Pub. No.: US 2007/0001711 A1
(43) Pub. Date: Jan. 4, 2007

(54) Organic light emitting display array substrate and method of performing test using the same

(76) Inventor: Won Kyu Kwak, Seongnam (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/472,688

(22) Filed: Jun. 21, 2006

(30) Foreign Application Priority Data
Jun. 29, 2005 (KR) 10-2005-57159

(51) Int. Cl. G01R 31/00

(52) U.S. Cl. 324/770

(57) ABSTRACT

An organic light emitting display array substrate on which display panels can be simultaneously tested on a substrate basis and a method of testing the display panels on the substrate is disclosed. In one embodiment, the organic light emitting display array substrate includes a plurality of panels formed on the substrate, a first wiring line group formed on each of the panels in a first direction, a pad unit formed on each of the panels to be electrically connected to the first wiring line group, a first power source line formed on each of the panels in the first direction to receive a first power source, and a second wiring line group formed on each of the panels in a second direction. The first wiring line group is electrically connected to a scan driver formed in each of the panels. The substrate can reduce test time and improve test efficiency. In addition, it can prevent a voltage drop and/or a signal delay.

### CROSS-REFERENCE TO RELATED APPLICATIONS

This application claims the benefit of Korean Patent Application No. 2005-57159, filed on Jun. 29, 2005, in the Korean Intellectual Property Office, the disclosure of which is incorporated herein by reference.

### BACKGROUND OF THE INVENTION

1. Field of the Invention

The present invention relates to an organic light emitting display array substrate and a method of testing display panels on the substrate. More particularly, the present invention relates to an organic light emitting display array substrate on which display panels can be simultaneously tested on a substrate basis before the substrate is divided into individual panels, and a method of testing the display panels on the substrate.

2. Discussion of Related Technology

In manufacturing organic light emitting display panels, a plurality of display panels are simultaneously formed on a substrate. Then, the substrate is scribed and divided into individual display panels. The following two methods have been employed to test such display panels.

In the first method, a substrate is first scribed and divided into individual panels. Then, the individual panels are separately tested. In this method, tests are performed using test equipment configured for testing a single display panel. One of the disadvantages of this method is that different test equipment must be used or jig required for a test must be changed, depending on the circuit wiring lines or size of the tested panels. In addition, the test efficiency is low because the panels are individually tested.

In the second method, a substrate is scribed and divided into rows or columns of display panels. Then, a row or a column of the panels is simultaneously tested. A method of testing a plurality of liquid crystal display (LCD) panels in a row or column is disclosed in Korean Patent Application Publication Nos. 2002-41674 and 1999-3277. In testing the panels, test pads are provided to both sides of a row of the panels. The references indicate that this test method is particularly applicable to a naked eye test.

In manufacturing an LCD, most tests can be performed using the naked eye. This is because inspection such as whether or not a foreign material is attached to the LCD can be easily performed with the naked eye even though liquid crystal is implanted between top and bottom substrates. Therefore, the second method described above does not increase test time. However, in the case of an organic light emitting display, a plurality of tests, which cannot be performed using the naked eye, need to be further performed on display panels with an organic emission layer inserted therein. Here, the tests for the organic light emitting display panels should be performed by an electric inspection as well as the naked eye because they proceed in the state that transistors, organic emission layers and the like are already formed. Accordingly, using the second method for organic light emitting display panels causes an increased test time. In order to reduce test time, tests need be performed on display panels on a substrate basis before the substrate is divided into rows or columns of display panels.

When an illumination test, a leakage current test, or an aging test is performed on organic light emitting display panels, test power source lines and signal lines must be provided to the panels. Therefore, in order to perform the tests on individual panels, it is required to properly arrange the test power source lines and signal lines on the panels. However, as the number of the power source lines and signal lines increases, the lines cannot be formed wide enough to avoid a voltage drop (IR drop) or a signal delay (RC delay) because of a lack of space on the panels.

### SUMMARY OF CERTAIN INVENTIVE ASPECTS

One aspect of the invention provides an organic light emitting display array substrate on which display panels can be tested before the substrate is divided into individual panels. Tests can be performed using signal lines on the panels, but with no additional test-only signal lines or power source lines.

The organic light emitting display array substrate comprises a plurality of panels formed on the substrate, a first wiring line group formed on each of the panels in a first direction, a pad unit formed on each of the panels to be electrically connected to the first wiring line group, a first power source line formed on each of the panels in the first direction to receive a first power source, and a second wiring line group formed on each of the panels in a second direction. The first wiring line group is electrically connected to a scan driver formed in each of the panels.

The organic light emitting display array substrate may further comprise a data driver formed on each of the panels for supplying data signals to data lines, a pixel unit for receiving the first power source, a second power source, scan signals, and the data signals to display images, and a test unit formed in each of the panels and connected to the second wiring line group to supply illumination test signals to the data lines. The first wiring line group may comprise a first wiring line for supplying scan control signals to the scan driver, a second wiring line for supplying a third power source to the scan driver, and a third wiring line for supplying a fourth power source to the scan driver. The scan driver may receive the scan control signals and the third and fourth power sources to supply scan signals to scan lines. The second wiring line group may comprise a fourth wiring line for supplying the second power source to the pixel unit and a fifth wiring line for supplying illumination signals to the test unit. The test unit may comprise a plurality of transistors connected to the data lines, respectively. The illumination signals may comprises an illumination control signal and the illumination test signal and the transistors are turned on by the illumination control signal to supply the illumination test signal to the data lines. When test on the plurality of panels formed on the substrate is completed, at least one of the end of the first power source line, the top of the first wiring line group, and the end of the second wiring line group may be cut off to float.

Another aspect of the invention provides a method of testing an organic light emitting display array substrate having a plurality of display panels before the substrate is divided into individual panels. Each of the panels has a first wiring line group and a scan driver and the first wiring line group is electrically connected to pads connected to the scan driver. The method comprises the steps of supplying a first power source to a first power source line formed in each of the plurality of panels formed on the substrate in a first direction, supplying a first driving signal to the first wiring line group formed in each of the panels in the first direction, generating scan signals in the scan driver in response to the first driving signal, supplying a second driving signal to a second wiring line group formed in each of the panels in a second direction, and supplying illumination test signals from a test unit formed in each of the panels to data lines in response to the second driving signal. The first driving signal may comprise scan control signals and third and fourth power sources for driving the scan driver. The second driving signal may comprise a second power source and illumination signals input to the test unit. The illumination signals may comprise an illumination control signal for controlling the test unit and the illumination test signal supplied to the data lines by the illumination control signal. A signal for determining whether the illumination of the panels is defective may be supplied as the illumination test signal. A signal for testing leakage current of the panels may be supplied as the illumination test signal. A signal for performing aging test on the panels may be supplied as the illumination test signal. The first and second driving signals may be supplied to only some of the plurality of first and second wiring line groups so that at least one of the illumination test, the leakage current test, and the aging test is performed only in some of the panels formed on the substrate. When tests on the plurality of panels are completed, at least one of the end of the first power source line, the top of the first wiring line group, and the end of the second wiring line group may be cut off.

### BRIEF DESCRIPTION OF THE DRAWINGS

Aspects and advantages of the invention will become apparent and more readily appreciated from the following description, taken in conjunction with the accompanying drawings.

FIG. 1 illustrates an organic light emitting display array substrate according to an embodiment of the invention;

FIG. 2 illustrates one embodiment of a display panel and wiring line groups of the organic light emitting display array substrate of FIG. 1;

FIG. 3 is a circuit diagram of one embodiment of a test unit of the organic light emitting display array substrate of FIGS. 1 and 2;

FIG. 4 is a circuit diagram of one embodiment of a pixel of the pixel unit of FIGS. 1 and 2;

FIG. 5 illustrates waveforms of control signals for controlling the pixel of FIG. 4;

FIG. 6 is a diagram illustrating an array of panels with test status associated with an embodiment of a method of performing tests on display panels on a substrate basis;

FIG. 7 is a diagram illustrating an array of panels with test status associated with another embodiment of a method of performing test on display panels on a substrate basis; and

FIG. 8 illustrates one embodiment of an organic light emitting display panel formed by scribing and dividing the substrate of FIG. 1 into individual panels.

### DETAILED DESCRIPTION OF CERTAIN INVENTIVE EMBODIMENTS

An organic light emitting display array substrate according to embodiments of the invention will be described in detail with reference to the accompanying drawings. In the drawings, like reference numerals indicate identical or functionally similar elements.

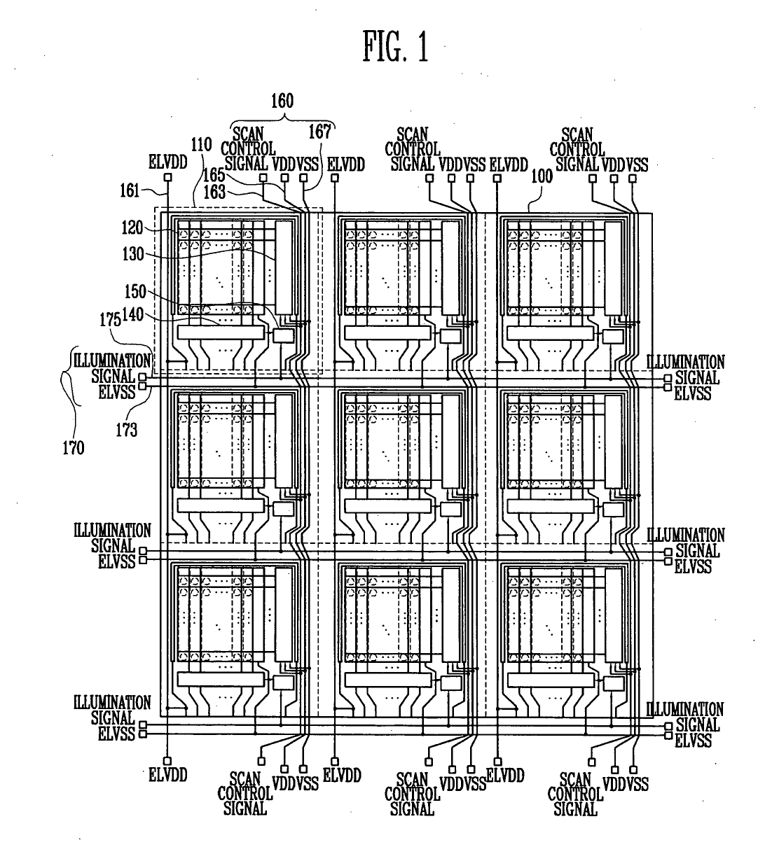

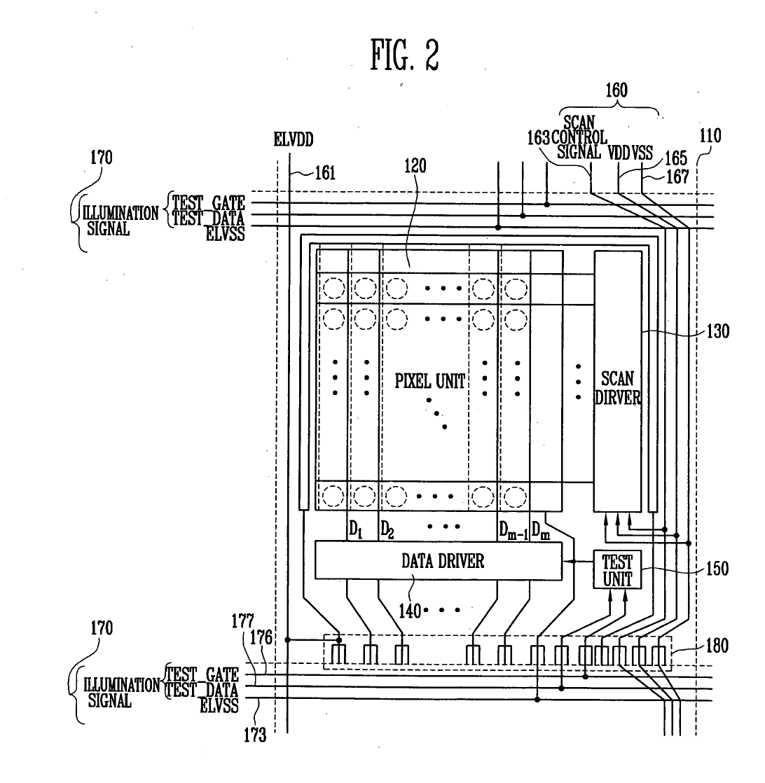

FIG. 1 illustrates an organic light emitting display array substrate according to an embodiment of the invention. FIG. 2 illustrates one embodiment of a display panel and wiring line groups of the organic light emitting display of FIG. 1.

Referring to FIGS. 1 and 2, the organic light emitting display array substrate 100 comprises a plurality of panels 110. Each of the panels 110 includes a pixel unit 120, a scan driver 130, a data driver 140, a test unit 150, a first wiring line group 160, a second wiring line group 170, and a first power source line 161.

The first wiring line group 160 includes a first, second, and third wiring lines 163, 165, and 167. The first wiring line group 160 is formed in a first or vertical direction. The first wiring line 163 receives scan control signals from the outside and supplies them to the scan driver 130. The second wiring line 165 receives a third power source VDD from the outside and supplies it to the scan driver 130. The third wiring line 167 receives a fourth power source VSS from the outside and supplies it to the scan driver 130. The first, second, and third wiring lines 163, 165, and 167 are electrically connected to pads formed in a pad unit 180 of each of the panels 110. The first, second, and third wiring lines 163, 165, and 167 may be used as signal lines and power source lines for driving the panels 110. The pads will be described in detail with reference to FIG. 8. According to one embodiment, additional space between the first, second, and third wiring lines 163, 165, and 167 is not required.

In one embodiment, the second wiring line group 170 includes a fourth wiring line 173 and a fifth wiring line 175. The second wiring line group 170 is formed in a second or horizontal direction.

The fourth wiring line 173 receives a second power source ELVSS from the outside and supplies it to pixels in the pixel unit 120. The fifth wiring line 175 receives illumination signals and supplies them to the test unit 150. The fourth and fifth wiring lines 173 and 175 are electrically connected to the pads formed in the pad unit 180 of each of the panels 110.

The first power source line 161 is formed in the first or vertical direction at the edge on the opposite side of the panel from the first wiring line group 160 in each of the panels 110. The first power source line 161 receives a first power source ELVDD from the outside and supplies it to the pixels in the pixel unit 120. The first power source line 161 is electrically connected to the pads in the pad unit 180.

The pixel unit 120 comprises a plurality of pixels (not shown). The pixels may comprise organic light emitting diodes (OLED). The pixel unit 120 receives the first power source ELVDD, the second power source ELVSS, scan signals, and data signals, and displays images.

The scan driver 130 sequentially supplies scan signals to scan lines. When tesing display panels, the scan driver 130 receives the scan control signals and the third and fourth power sources VDD and VSS from the first wiring line group 160. The scan driver then generates the scan signals for testing the display panels on a substrate basis. On the other hand, after the substrate is scribed and divided into individual panels, the scan driver 130 receives the scan control signals and the third and fourth power sources VDD and VSS from the pads and then generates the scan signals.

The data driver 140 receives data from the outside through the pads in the pad unit 180 and generates data signals. The data signals are supplied to the pixel unit 120. According to one embodiment, the data driver 140 is mounted on the panel 110. In other embodiments, the data driver may not be provided on the panel 110.

The test unit 150 receives illumination signals from the fifth wiring line 175. The test unit 150 then supplies the illumination signals to data lines. The illumination signals may include an illumination test signal, an aging test signal, and a leakage current test signal for the pixels in the pixel unit 120. The fifth wiring line 175 may comprise an illumination control signal line 176 and an illumination test signal line 177 as shown in FIG. 2. The illumination control signal line 176 receives an illumination control signal TEST_GATE from the outside and supplies it to the test unit 150. The illumination test signal line 177 receives an illumination test signal TEST_DATA from the outside and supplies it to the test unit 150. The test unit 150 then supplies the illumination signals to the data lines D1 to Dm according to the illumination control signal TEST_GATE and the illumination test signal TEST_DATA. In this embodiment, the illumination signals comprise the aging and the leakage current test signals as well as the illumination test signal TEST_DATA for the pixels.

The test unit 150 supplies the illumination signals to the data lines D1 to Dm only when tests on display panels are performed on a substrate basis. The test unit 150, however, does not supply the illumination signals to the data lines D1 to Dm in other cases. After the substrate is scribed and divided into the panels 110, it is the data driver 140 that supplies the illumination signals to the data lines D1 to Dm.

The position of the test unit 150 may vary depending on the circuit design of the panel. In one embodiment, the test unit 150 is formed on one side of the data driver 140 as shown in FIGS. 1 and 2. In other embodiments, the test unit 150 may be formed over the data driver 140 or may be integrated with the data driver 140.

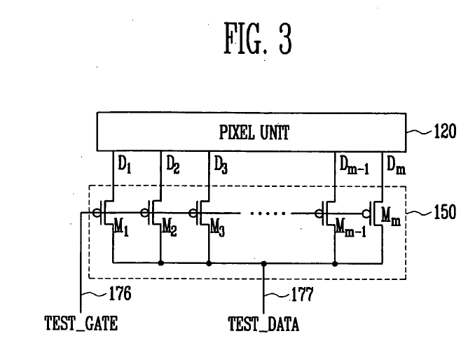

FIG. 3 is a circuit diagram of one embodiment of the test unit of FIGS. 1 and 2. Referring to FIG. 3, the test unit 150 may comprise a plurality of transistors M1 to Mm. In one embodiment, the transistors M1 to Mm may comprise PMOS transistors as shown in FIG. 3. In other embodiments, the transistors M1 to Mm may comprise other types of transistors such as NMOS transistors. Each of the transistors M1 to Mm has a gate, a first, and a second electrode. The gate electrodes of the transistors M1 to Mm are connected to the illumination control signal line 176. The first electrodes of the transistors M1 to Mm are connected to the data lines D1 to Dm. The second electrodes of the transistors M1 to Mm are connected to the illumination test signal line 177.

The testing process for the panels will be described below in detail. First, the scan control signals from the first wiring line 163, the third power source VDD from the second wiring line 165, and the fourth power source VSS from the third wiring line 167 are supplied to the scan driver 130. Then, the scan driver 130 generates and supplies scan signals to the scan lines.

The illumination control signal TEST_GATE of a low voltage level is supplied from the illumination control signal line 176 to the transistors M1 to Mm, turning on the transistor M1 to Mm. When the transistors M1 to Mm are turned on, the illumination test signal TEST_DATA is supplied through the illumination test signal line 177 to the data lines D1 to Dm. Then, the pixels in each of the panels 110 receive the scan signals and the illumination test signal TEST_DATA, and emit light in a predetermined form according to the illumination test signal TEST_DATA.

Some pixels may fail to emit light according to the test signal due to a defect. Therefore, it is possible to determine whether the pixels are defective. Since identical illumination test signals TEST_DATA are supplied to the pixels, it is also possible to measure the white balance of the pixels and to detect progressive defects.

In an aging test on the panels, the aging test signal is applied as an illumination test signal TEST_DATA. The aging test signal applies a high bias voltage or current to the data lines D1 to Dm to detect progressive defects of OLEDs. After setting the substrate 100 at a low or high temperature, the illumination test signal TEST_DATA is supplied to the pixels so as to determine whether the OLEDs are normally operating at the set temperature.

In a current leakage test, the leakage current test signal is applied as an illumination test signal TEST_DATA. The current leakage test is performed by measuring a current that flows to the first power source line 161 and the fourth wiring line 173 while the first and second power sources ELVDD and ELVSS are applied to the pixels. The test unit 150 is turned off while the first and second power sources ELVDD and ELVSS are applied to the pixels, Then, a current that flows to the first power source line 161 and the fourth wiring line 173 is measured to detect a leakage current. In one embodiment, this test may be performed only on some of the panels 110 on the substrate 100.

FIG. 4 is a circuit diagram illustrating one embodiment of a pixel in the pixel unit of FIGS. 1 and 2. The pixel comprises a pixel circuit 410 and an OLED.

The pixel circuit 410 is connected to an n-th scan line Sn, an (n−1)th scan line Sn-1, an n-th emission control signal line EMn, an m-th data line Dm, a first power source ELVDD, an initializing power source Vinit, and the OLED.

A first electrode of the OLED is connected to the pixel circuit 410 and a second electrode of the OLED is connected to the second power source ELVSS. The OLED generates light according to a current supplied from the pixel circuit 410.

The pixel circuit 410 includes first to sixth transistors T1 to T6 and a first capacitor C1.

The gate, first, and second electrodes of the first transistor T1 are connected to a first, second, and third nodes N1, N2, and N3, respectively. The first transistor T1 controls a current that flows from the second node N2 to the third node N3 in response to a voltage supplied to the gate electrode of the transistor.

The gate, first, and second electrodes of the second transistor T2 are connected to the n-th scan line Sn, the m-th data line Dm, and the second node N2, respectively. The second transistor T2 is turned on when a scan signal is supplied to the n-th scan line Sn. When the second transistor T2 is turned on, the data signal is supplied from the m-th data line Dm to the second node N2.

The gate, first, and second electrodes of the third transistor T3 are connected to the n-th scan line Sn, the third node N3, and the first node N1, respectively. The third transistor T3 is turned on when the scan signal is supplied to the n-th scan line Sn. When the third transistor T3 is turned on, an electric current flows through the first transistor T1. Therefore, the first transistor T1 operates as a diode.

The gate, first, and second electrodes of the fourth transistor T4 are connected to the (n−1)th scan line Sn-1, the initializing power source Vinit, and the first node N1, respectively. The fourth transistor T4 is turned on when a scan signal is supplied to the (n−1)th scan line Sn-1. Then, the fourth transistor T4 supplies the initializing power source Vinit to the first node N1.

The gate, first, and second electrodes of the fifth transistor T5 are connected to the n-th emission control signal line En, a fourth node N4, and the second node N2, respectively. The fifth transistor T5 is turned on when an emission control signal is not supplied to the n-th emission control signal line En (i.e., when a signal of a low voltage level is input to the n-th emission control signal line En). Then, the fifth transistor T5 supplies the voltage of the first power source ELVDD to the second node N2.

The gate, first, and second electrodes of the sixth transistor T6 are connected to the n-th emission control signal line EMn, the third node N3, and the anode electrode of the OLED, respectively. The sixth transistor T6 is turned on when the emission control signal is not supplied to the n-th emission control signal line EMn. Then, the sixth transistor T6 electrically connects the third node N3 to the OLED.

One terminal of the first capacitor C1 is connected to the fourth node N4. The other terminal of the first capacitor C1 is connected to the first node N1. When the scan signal is supplied to the n-th scan line Sn, the first capacitor C1 is charged with a voltage corresponding to a difference between the voltage of the data signal and the threshold voltage Vth of the first transistor T1. The charged voltage is maintained for one frame.

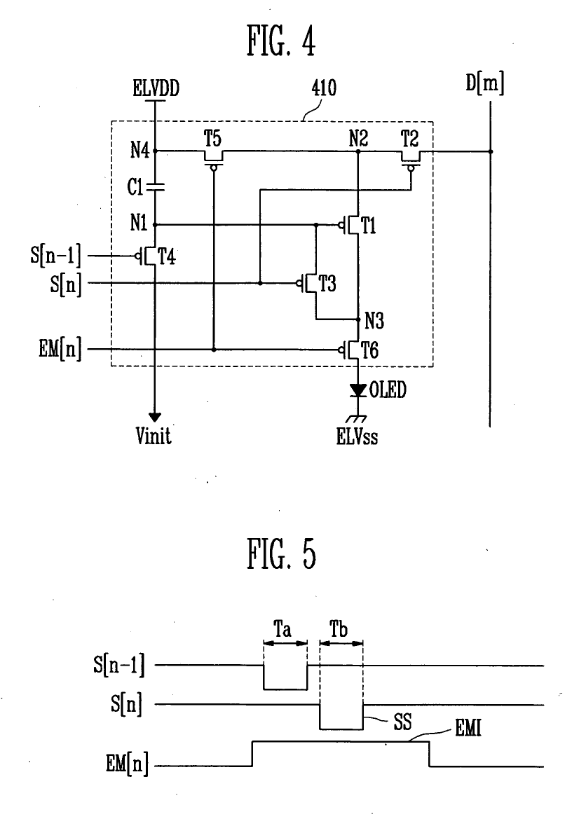

FIG. 5 illustrates waveforms of control signals for controlling the pixel of FIG. 4. The scan signal SS and the emission control signal EMI are supplied to the (n−1)th scan line Sn-1 and the n-th emission control signal line EMn, respectively, during a period Ta in FIG. 5. When the emission control signal EMI is supplied to the n-th emission control signal line EMn, the fifth and sixth transistors T5 and T6 are turned off. When the scan signal SS is supplied to the (n−1)th scan line Sn-1, the fourth transistor T4 is turned on. When the fourth transistor T4 is turned on, the voltage of the first node N1 changes to the voltage of the initializing power source Vinit. Here, the voltage value of the initializing power source Vinit is lower than that of the data signal.

Then, the scan signal SS is supplied to the n-th scan line Sn during a period Tb in FIG. 5. When the scan signal SS is supplied to the n-th scan line Sn, the second and third transistors T2 and T3 are turned on. When the third transistor T3 is turned on, an electric current flows through the first transistor T1. The first transistor T1 now operates as a diode.

When the second transistor T2 is turned on, the data signal is supplied from the m-th data line Dm to the second node N2. Because the voltage value of the first node N1 has changed to that of the initializing power source Vinit, the voltage of the first node N1 is lower than that of the second node N2. Therefore, the first transistor T1 is now turned on. When the first transistor T1 is turned on, the data signal is supplied from the second node N2 to the first node N1 via the first and third transistors T1 and T3. Then, the first capacitor C1 is charged with a voltage corresponding to a voltage difference between the first node N1 and the fourth node N4. The voltage of the fourth node N4 is the same as that of the first power source ELVDD.

Since the data signal is supplied from the second node N2 to the first node N1 through the first and third transistors T1 and T3, the voltage value of the first node N1 is the voltage of the data signal less the threshold voltage of the first transistor T1. Therefore, a voltage corresponding to a difference between the voltage of the data signal and the threshold voltage of the first transistor T1 is charged in the first capacitor C1.

Subsequently, the emission control signal EMI is not supplied to the n-th emission control signal line EMn as shown in FIG. 5. Accordingly, the fifth and sixth transistors T5 and T6 are turned on. When the fifth transistor T5 is turned on, the voltage of the first power source ELVDD is supplied to the second node N2 via the fifth transistor T5. When the sixth transistor T6 is turned on, a current corresponding to the voltage charged in the first capacitor C1 is supplied from the first transistor T1 to the OLED. Therefore, the OLED generates light corresponding to the data signal regardless of the threshold voltage of the first transistor T1.

FIG. 6 illustrates an embodiment of a method of testing organic light emitting display panels on a substrate basis, i.e., before dividing the substrate into individual panels. Referring to FIGS. 1 and 6, signals are supplied to the first and second wiring line groups 160 and 170 connected to a specific panel 300 on the substrate 100. The first power source ELVDD is supplied to the first power source line 161 connected to the specific panel 300. Then, a test is performed on the specific panel 300. During the test, no test is performed on other panels 110.

Referring to FIGS. 1, 2 and 6, the test process will now be described below in detail. First, the scan driver 130 on the panel 300 generates scan signals according to signals supplied from the first wiring line group 160. The test unit 150 on the panel 300 supplies an illumination test signal TEST_DATA to the data lines D1 to Dm according to signals supplied from the second wiring line group 170. Then, an aging test, leakage current test, and illumination test are sequentially performed on the panel 300 according to the illumination test signal TEST_DATA. In other embodiments, the sequence of the tests may be different. In addition, various other types of tests may be performed on a selected panel.

In another embodiment, tests may be simultaneously performed on at least two panels on the substrate. In this embodiment, signals are supplied to a plurality of first and second wiring line groups 160 and 170 and first power source lines 161 connected to the at least two panels 110.

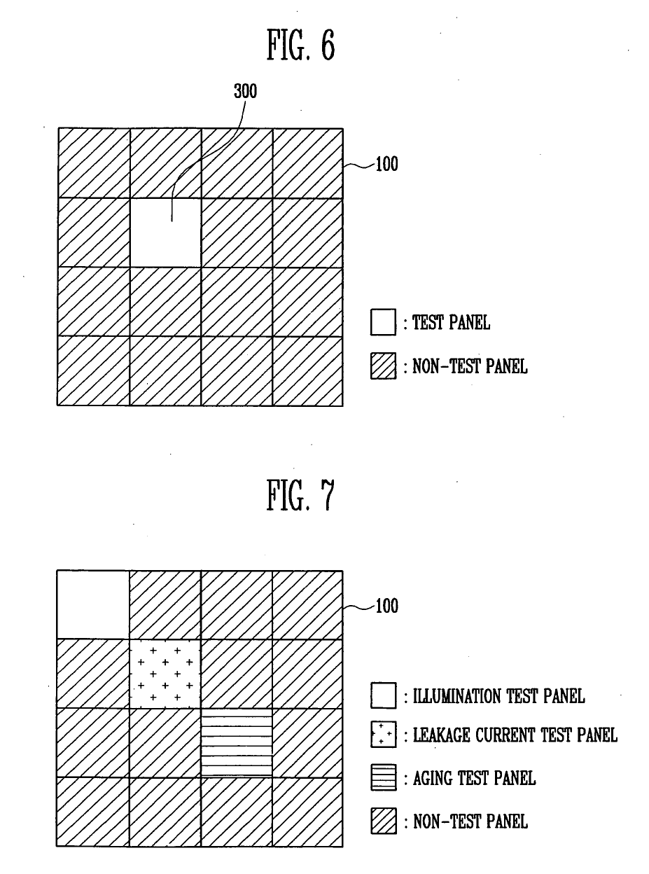

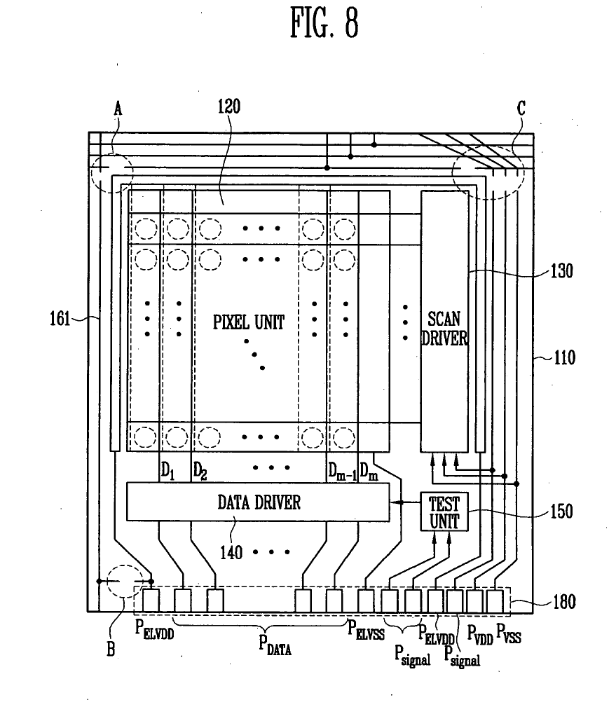

FIG. 7 illustrates another embodiment of a method of simultaneously testing display panels on a substrate basis. Referring to FIGS. 1, 2, and 7, power sources and signals are simultaneously supplied to a plurality of panels. In FIG. 7, tests are performed on three panels: a panel in the first row and the first column, a panel in the second row and the second column, and a panel in the third row and the third column on the substrate 100. The power sources and signals are provided to the first and second wiring line groups 160 and 170 and first power source lines 161 connected to the panels.

An illumination test signal is supplied through the illumination test signal line 177 to the panel in the first row and first column. Then, an illumination test is performed on the panel.

A leakage current test signal is supplied through the illumination test signal line 177 to the panel in the second row and second column. Then, a leakage current test is performed on the panel.

An aging test signal is supplied through the illumination test signal line 177 to the panel in the third row and third column. Then, an aging test is performed on the panel. The illumination test, the leakage current test, and the aging test may be simultaneously or sequentially performed. When tests on the selected panels are completed, the tests as shown in FIG. 7 may be performed on the adjacent panels or other panels on the substrate. The tests are continued until all the panels on the substrate are tested.

FIG. 8 illustrates an embodiment of an organic light emitting display panel. The panel may be obtained by scribing and dividing a substrate as shown in FIG. 1 into individual panels. Referring to FIG. 8, the organic light emitting display panel 110 includes a pixel unit 120, a scan driver 130, a data driver 140, a test unit 150, and a pad unit 180.

The pixel unit 120 may comprise a plurality of pixels (not shown) including OLEDs. The pixel unit 120 receives a first power source ELVDD from a first pad P_{ELVDD}, a second power source E_{LVSS} from a third pad P_{ELVSS}, scan signals from the scan driver 130, and data signals from the data driver 140. The pixel unit 120 displays images according to the above signals.

The scan driver 130 receives scan control signals from fourth pads P_{signal}, a third power source VSS from a fifth pad P_{VDD}, and a fourth power source VSS from a sixth pad P_{VSS}, and generates scan signals. The scan signals are supplied to the pixel unit 120.

The data driver 140 receives data from a plurality of second pads P_{DATA}, and generates data signals. The data signals are supplied to the pixel unit 120.

The test unit 150 receives illumination signals from the fourth pads P_{signal}. When a test is not performed, the illumination signals are supplied to the test unit 150 so that the test unit 150 does not operate. For example, when an illumination control signal TEST_GATE of a high voltage level and an illumination test signal TEST_DATA of a low voltage level are supplied to the test unit 150, the test unit 150 does not operate.

The position of the test unit 150 may vary depending on the circuit design of the panel. In one embodiment, the test unit 150 is formed on one side of the data driver 140 as shown in FIG. 8. In other embodiments, the test unit 150 may be formed over the data driver 140 or may be integrated with the data driver 140.

The pad unit 180 supplies power sources and signals from the outside to the panel 110. The first pad P_{ELVDD} connects the first power source ELVDD to the pixel unit 120. The second pads P_{DATA} supply data to the data driver 140. The third pad P_{ELVSS} connects the second power source ELVSS to the pixel unit 120. The fourth pads P_{signal} supply illumination signals to the test unit 150 and scan control signals to the scan driver 130. The fifth pad P_{VDD} supplies the third power source VDD to the scan driver 130. The sixth pad P_{VSS} supplies the fourth power source VSS to the scan driver 130.

In this embodiment, at least one of the fourth pads P_{signal} of the pad unit 180 and the fifth and sixth pads P_{VDD} and P_{VSS} are electrically connected to the first, second, and third wiring lines 163, 165, and 167. Referring back to FIGS. 1 and 2, the first, second, and third wiring lines 163, 165, and 167 have been used for testing display panels on a substrate basis. On the other hand, after the substrate is scribed and divided into individual display panels, the first, second, and third wiring lines 163, 165, and 167 are used as signal lines for driving the individual panels. Therefore, identical wiring lines can be used for both testing and driving the panels. This arrangement saves space on the panels. Because the panels can have enough space for wiring lines, the wiring lines can be formed wide enough to avoid a voltage drop and/or a signal delay.

The wiring lines are exposed after the substrate is scribed and divided into panels. The wiring lines are therefore vulnerable to static electricity ESD. Thus, in one embodiment, the wiring lines may be cut off to float. For example, an upper part of the first power source line 161 may be cut off as denoted by A in FIG. 8. Also, a line that has connected the first power source line 161 to the first pad P_{ELVDD} may be cut off as denoted by B in FIG. 8. Static electricity generated by the first power source line 161 therefore does not affect the power source from the first pad P_{ELVDD} to the pixel unit 120. The upper ends of the signal lines that receive signals from the fourth pads P_{signal} may also be cut off as denoted by C in FIG. 8. However, the power source lines and signal lines that supply driving signals from the outside to the panel 110 are kept intact. In one embodiment, the lines are disconnected after testing the display panels but before scribing and dividing the substrate. In other embodiments, the line cutting may be carried out after scribing and dividing the substrate.

As described above, according to the embodiments of the invention, display panels can be simultaneously tested on a substrate basis. Therefore, tests on the display panels can be performed with less time and a better efficiency than conventional methods. In addition, identical wiring lines can be used both for testing the display panels on a substrate and for driving the finished individual panels. Therefore, the panels do not need space for additional test-only lines. Instead, the panels may use the space to have wiring lines wide enough to prevent a voltage drop (IR drop) and/or a signal delay (RC delay). In addition, exposed lines are disconnected after tests so as to prevent the influence of static electricity.

Although various embodiments of the invention have been shown and described, it will be appreciated by those technologists in the art that changes might be made in these embodiments without departing from the principles and spirit of the invention, the scope of which is defined in the claims and their equivalents.

What is claimed is:

1. An organic light emitting display array substrate comprising:
an array of a plurality of organic light emitting display panels;
at least one first wiring line group formed across the panels in a first direction, the first wiring line group being electrically connected to a scan driver and a pad unit on each of the panels;
at least one first power source line formed across the panels in the first direction, the first power source being configured to receive a first power source; and
at least one second wiring line group formed across the panels in a second direction.

2. The organic light emitting display array substrate of claim 1, wherein each of the panels further comprises:
a data driver for supplying data signals to data lines;
a pixel unit configured to display images, the pixel unit receiving the first power source, a second power source, scan signals, and the data signals; and
a test unit connected to the second wiring line group, the test unit being configured to supply illumination test signals to the data lines.

3. The organic light emitting display array substrate of claim 1, wherein the first wiring line group comprises:
a first wiring line configured to supply scan control signals to the scan driver;
a second wiring line configured to supply a third power source to the scan driver; and
a third wiring line configured to supply a fourth power source to the scan driver.

4. The organic light emitting display array substrate of claim 3, wherein the scan driver receives the scan control signals and the third and fourth power sources, and wherein the scan driver is configured to supply scan signals to scan lines.

5. The organic light emitting display array substrate of claim 2, wherein the second wiring line group comprises:
a fourth wiring line configured to supply the second power source to the pixel unit; and
a fifth wiring line configured to supply illumination signals to the test unit.

6. The organic light emitting display array substrate of claim 5, wherein the test unit comprises a plurality of transistors, each of the transistors being connected to a respective one of the data lines.

7. The organic light emitting display array substrate of claim 6,
wherein the illumination signals comprise an illumination control signal and illumination test signals, and
wherein the transistors are configured to supply the illumination test signals to the data lines according to the illumination control signal.

8. The organic light emitting display array substrate of claim 1, wherein at least one of the first power source line, the first wiring line group, and the second wiring line group is disconnected.

9. A method of testing organic light emitting display panels on the organic light emitting display array substrate of claim 1, the method comprising the steps of:
supplying a first power source to the first power source line;
supplying a first driving signal to the first wiring line group;
generating scan signals in the scan driver according to the first driving signal;
supplying a second driving signal to the second wiring line group; and
supplying illumination test signals from a test unit formed in each of the panels to data lines according to the second driving signal.

10. The method of claim 9, wherein the first driving signal comprises scan control signals and third and fourth power sources for driving the scan driver.

11. The method of claim 9, wherein the second driving signal comprises a second power source and illumination signals to be supplied to the test unit.

12. The method of claim 11, wherein the illumination signals comprise:
an illumination control signal for controlling the test unit; and
illumination test signals to be supplied to the data lines.

13. The method of claim 12, wherein a signal for determining whether the illumination of the panels is defective is supplied as an illumination test signal.

14. The method of claim 13, wherein the first and second driving signals are supplied only to a part of the plurality of first and second wiring line groups on the substrate so that the illumination test is performed only on a part of the panels on the substrate.

15. The method of claim 12, wherein a signal for testing a leakage current of the panels is supplied as an illumination test signal.

16. The method of claim 15, wherein the first and second driving signals are supplied only to a part of the plurality of first and second wiring line groups on the substrate so that the leakage current test is performed only on a part of the panels on the substrate.

17. The method of claim 12, wherein a signal for performing aging test on the panels is supplied as an illumination test signal.

18. The method of claim 17, wherein the first and second driving signals are supplied only to a part of the plurality of first and second wiring line groups on the substrate so that the aging test is performed only on a part of the panels on the substrate.

19. The method of claim 9, further comprising disconnecting at least one of the first power source line, the first wiring line group, and the second wiring line group after tests on the panels are completed.

20. An organic light emitting display panel made by dividing the organic light emitting display array substrate of claim 1 into a plurality of organic light emitting display panels.

21. The organic light emitting display panel of claim 20, wherein at least one of the first power source line, the first wiring line group, and the second wiring line group is disconnected.
